(19) United States
(12) Patent Application Publication
(10) Pub. No.: US 2025/0309527 A1
(43) Pub. Date: Oct. 2, 2025

(54) ANTENNA

(71) Applicant: BAE SYSTEMS plc, London (GB)

(72) Inventor: Marek Sebastian PIECHOCINSKI, Filton Bristol (GB)

(73) Assignee: BAE SYSTEMS plc, London (GB)

(21) Appl. No.: 18/864,165

(22) PCT Filed: May 5, 2023
(86) PCT No.: PCT/GB2023/051199

§ 371 Date: Nov. 8, 2024

(30) Foreign Application Priority Data
May 9, 2022 (EP) 22275059.8
May 9, 2022 (GB) 2206712.8

(51) Int. Cl. H01Q 1/36; H01Q 21/06; H10N 30/85

(52) U.S. Cl. CPC H01Q 1/364; H01Q 21/061; H10N 30/85

(57) ABSTRACT

An antenna is provided. The antenna may comprise a magnetostrictive layer configured to, in receive mode, convert a magnetic field of a detected electromagnetic wave into mechanical strain, and a piezoelectric layer configured to, in receive mode, receive the mechanical strain from the magnetostrictive layer and produce a voltage output based thereon. The piezoelectric layer may comprise a memristive material.

### FIELD

The present invention relates generally to an antenna, and more specifically to an antenna comprising a memristive material. A related antenna array and method are also provided.

### BACKGROUND

A wireless communication system operating in a radio frequency range requires an antenna to convert an electromagnetic wave into an electrical current indicative of the received signal and vice versa. Typically, the antenna is driven by an analogue circuit connected to a signal processing unit. In most systems, the signal received by the antenna does not travel directly to a logic element responsible for decoding the signal and extracting the transmitted information. Instead, the signal typically has to travel through modules such as an analog-to-digital (ADC) converter, memory, and/or a digital signal processor (DSP). Each of these modules has associated noise sources, thereby degrading the signal-to-noise-ratio (SNR) of the system.

Furthermore, such modules include parasitic elements which introduce propagation delay, increasing the time interval between the signal being received by the antenna and the information contained within the signal being extracted. A different approach is therefore required in order to provide a device capable of faster extraction of the information contained within the received signal.

It is an example aim of example embodiments of the present invention to at least partially avoid or overcome one or more disadvantages of the prior art, whether identified herein or elsewhere, or to at least provide a viable alternative to existing apparatus and methods.

### SUMMARY

According to an aspect of the present invention, there is provided an antenna comprising a magnetostrictive layer configured to, in receive mode, convert a magnetic field of a detected electromagnetic wave into mechanical strain, and a piezoelectric layer configured to, in receive mode, receive the strain from the magnetostrictive layer and produce a voltage output based thereon, wherein the piezoelectric layer comprises a memristive material. Thus, an antenna having an intrinsic memory and signal processing capability can be provided, thereby enabling faster extraction of information contained within the received signal. Computation can be performed directly in the memory element, which also performs a sensing operation to thereby detect and process received signals.

In transmit mode, the piezoelectric layer may be configured to receive a voltage input and produce mechanical strain based thereon. and the magnetostrictive layer may be configured to receive the mechanical strain produced by the piezoelectric layer to produce and output an electromagnetic wave based thereon. As such, the antenna can employ the piezoelectric layer comprising the memristive material in transmission of signals, in addition to the reception.

The piezoelectric layer may be arranged to be set to a defined condition by an application of a voltage and/or charge. Thus, due to the inherent properties of the memristive material comprised therein, the piezoelectric layer can be set to a desired condition in an easy manner.

The piezoelectric layer may be arranged to be set to the defined condition prior to a receiving and/or transmitting operation of the antenna being performed. As such, the antenna can be preset (in other words, pre-programmed) prior to normal use and therefore can be considered as a programmable system.

Setting the piezoelectric layer to the defined condition may comprise varying a conductance of the piezoelectric layer by application of the voltage. The conductance of the memristive material is closely associated with synaptic weights, i.e. the strength of synaptic connections. Thus, by applying a voltage, the conductance can be decreased and/or increased to actualise the forgetting and learning behaviour of the piezoelectric layer, respectively, thereby exhibiting synaptic behaviour similar to biological systems.

The conductance of the piezoelectric layer may be varied based on at least one of a frequency of the applied voltage and polarity of the applied voltage. As the conductance of the memristive material is dependent on the stimulated pulse shape and frequency, the properties of the piezoelectric layer can be easily modified.

The piezoelectric layer may be configured to retain the set condition after the application of the voltage. Thus, the piezoelectric layer can act as a non-volatile memory, due to the presence of the memristive material.

The piezoelectric layer may be configured to produce the voltage output based on a charge resulting from the received strain and the set condition of the piezoelectric layer. Thus, the antenna can produce an output based on not only the detected signal, but also the set state of the piezoelectric layer.

The piezoelectric layer may be configured to produce the voltage output when a charge resulting from a received strain is equal to a threshold value defined based on the set condition of the piezoelectric layer. Thus, the antenna can produce an output only when the pre-programmed signal pattern is acquired, disregarding signal without the desired characteristic as noise. This is done by the antenna without interaction with any additional processing units, thereby reducing propagation delay of the signal and thus reducing the time taken for the antenna to extract information from the desired signal.

The memristive material may comprise annealed aluminium nitride, AlN. Thus, the antenna can be manufactured used readily available materials. thereby improving manufacturability and reducing cost.

According to another aspect of the invention, provided is an antenna array comprising a plurality of antennas as described herein. Thus, an antenna having an intrinsic signal processing capability can be provided, thereby enabling faster extraction of information contained within the received signal. Computation can be performed directly in the memory element, which also performs a sensing operation to thereby detect and process received signals.

Each of the plurality of antennas of the antenna array may be arranged to individually be set to a defined condition by application of a voltage. Thus, greater programmability can be achieved, as each of the individual antennas can be set to a condition enabling identification of a particular signal.

According to another aspect of the invention, provided is a method of manufacturing an antenna, the method comprising the steps of providing a piezoelectric layer comprising a memristive material, and providing a magnetostrictive layer disposed on the piezoelectric layer. Thus, an antenna having an intrinsic signal processing capability can be provided, thereby enabling faster extraction of information contained within the received signal. Computation can be performed directly in the memory element, which also performs a sensing operation to thereby detect and process received signals.

The method may comprise the step of providing annealed aluminium nitride, AlN, as the memristive material. Thus, the antenna can be manufactured used readily available materials, thereby reducing cost.

### BRIEF DESCRIPTION OF THE FIGURES

Embodiments of the invention will now be described by way of example only with reference to the figures, in which:

FIG. 1 schematically depicts an antenna, in accordance with an example embodiment;

FIG. 2 schematically depicts a thin-film bulk acoustic resonator, FBAR, comprising a piezoelectric layer, in accordance with an example embodiment;

FIG. 3 schematically depicts an antenna array comprising a plurality of antennas, in accordance with an example embodiment;

FIG. 4 schematically depicts a method of manufacturing an antenna, in accordance with an example embodiment.

### DETAILED DESCRIPTION

As discussed above, there are numerous disadvantages associated with existing antennas. These range from a significant expense associated with the existing antennas due to the amount of circuitry required, to delay in extracting information from the signal received by the antenna, or the amount of noise that is erroneously picked up instead of the desired signal. In general, there exists no relatively inexpensive, flexible yet simple design that would allow the antenna to process the received signal in the element also performing the sensing operation.

According to the present disclosure, it has been realised that the problems associated with the existing approaches can be overcome in an inexpensive and effective manner. In particular, the present disclosure provides a magnetoelectric antenna comprising a memristive material.

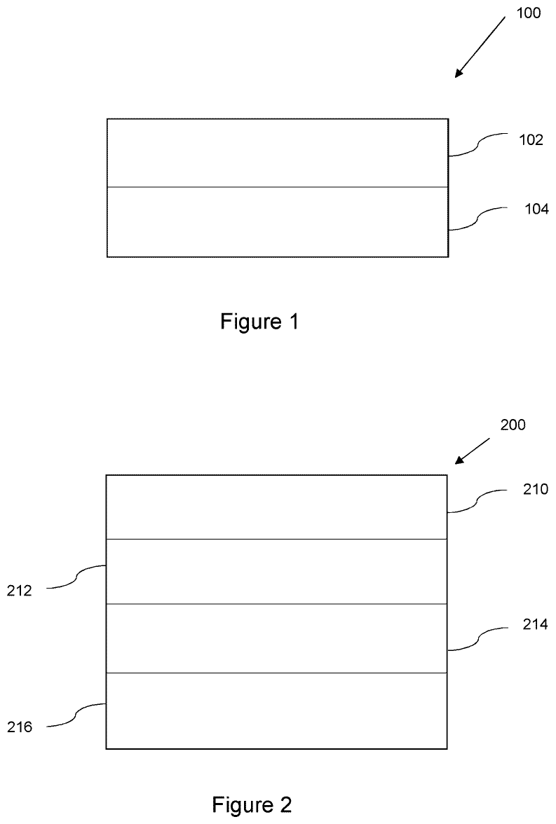

FIG. 1 schematically depicts an antenna in accordance with an example embodiment. In this example, the antenna 100 comprises a magnetostrictive layer 102 and a piezoelectric layer 104. Importantly, the piezoelectric layer 104 comprises a memristive material.

The antenna 100 may be a thin-film bulk acoustic resonator (FBAR) antenna. As the antenna 100 operates at the acoustic resonant frequency rather than of an EM wave resonant frequency, the size of the antenna can be significantly reduced, to a size comparable to the electromagnetic wavelength, without performance degradation. As such, the antenna 100 may be particularly suitable for use in applications where high resonant frequency, small size and low weight are desirable.

The antenna 100 receives and transmits electromagnetic waves through the magnetoelectric effect at its acoustic resonance frequency. During a receiving operation of the antenna 100, the magnetostrictive layer 102 is configured to convert a magnetic field of a detected electromagnetic wave into mechanical strain, to be received by the piezoelectric layer 104. The piezoelectric layer 104 produces a voltage output based on the strain received from the magnetostrictive layer 102. In detail, in receive mode, the magnetostrictive layer 102 may sense H-components of electromagnetic waves, which induce an oscillating strain transferred to the piezoelectric layer 104. The piezoelectric layer 104 may then produce a voltage output.

Conversely, during a transmitting operation of the antenna 100, the piezoelectric layer 104 is configured to receive a voltage input and produce mechanical strain based thereon. Such voltage input may originate from the antenna 100 itself, or from an external component of an antenna system. The magnetostrictive layer 102 is configured to then receive the mechanical strain produced by the piezoelectric layer 104 to produce and output an electromagnetic wave based thereon. In detail, the piezoelectric layer 104 may receive an alternating voltage input to produce an oscillating mechanical strain. In response to the mechanical excitation, the magnetostrictive layer 102 may then induce a magnetisation oscillation, or a magnetic current, that radiates electromagnetic waves to therefore transmit a signal.

As mentioned above, the piezoelectric layer 104 comprises a memristive material. Notably, the memristive material exhibits non-volatile memory characteristics and continuous conductance change property, therefore making it suitable for use in neuromorphic systems. A memristive material can be compared to a synapse in a brain.

The cellular mechanism that underlies learning and memory in human and animal brains is called long-term potentiation (LTP). LTP is a persistent strengthening of synapses based on recent patterns of activity. These are patterns of synaptic activity that produce a long-lasting increase in signal transmission between two neurons. Short-term potentiation (STP) refers to a process in which synaptic transmission is transiently enhanced. In this manner,

STP can be thought of as short-term memory. STP can change into LTP through the process of repeated impressions involving many biological changes.

In general terms, a memristor (i.e., a memristive device) is a two-terminal resistive switching device that can maintain its internal resistance states depending on the history of applied voltages/currents. The two terminals behave similarly to an axon and dendrite that connect pre-neurons and post-neurons of a synapse, with the conductance of the switching layers comparable to the weight of the synapse. By changing the conductance of the memristor to a set state, the device can be used to realise the memorisation function of the human brain, by simulating the change from an unmemorised state to the STP and LTP states.

The piezoelectric layer 104 may be set to a defined condition by application of a voltage. Setting the piezoelectric layer 104 to the defined condition may comprise varying a conductance of the piezoelectric layer 104 by application of the voltage or charge. In particular, by applying a voltage to the piezoelectric layer 104, the conductance of the memristive material comprised in the piezoelectric layer 104 can be modified, thereby realising the memorisation function described above. The voltage to be applied to the piezoelectric layer 104 may be an external bias voltage/charge, or an internal charge produced by the antenna 100 due to the piezoelectric effect.

Similarly, as the two quantities are intrinsically linked, electrical resistance of the piezoelectric layer 104 may also be modified through application of a voltage. In particular, the resistance of the memristive material comprised in the piezoelectric layer 104 may be modified in such way.

The condition (or state) of the piezoelectric layer 104 may depend on the prior state, amplitude of the applied voltage, and acquisition time of the voltage/signal. For example, after application of a first voltage, the condition of the piezoelectric layer 104 may be changed from an initial state to a first state. If a second voltage is applied to the piezoelectric layer 104 after the first voltage has been applied, the condition of the piezoelectric layer 104 may be changed from the first state to a second state.

The conductance of the piezoelectric layer 104 may be varied based on at least one of a frequency of the applied voltage and the polarity of the applied voltage. For example, by applying continuous positive voltage pulses, the conductance of the memristive material comprised in the piezoelectric layer 104 can be changed from an initial state to a higher state. Conversely, by applying negative voltage pulses, the conductance of the memristive material 104 can be changed from an initial state to a lower state. The conductance of the memristive material may also be changed by modifying a duration of the applied voltage.

The piezoelectric layer 104 may be configured to retain the set condition after the application of the voltage. As discussed above, a voltage may be applied in order to change the conductance of the memristive material comprised in the piezoelectric layer 104 can be changed from an initial state to a higher state. This change in conductance of the memristive material is retained for a period of time after the application of the voltage has ceased, thereby enabling the non-volatile memory operation of the memristive material. In other words, there is no need for a constant voltage application in order to vary the conductance of the memristive material in the piezoelectric layer 104. Varying the conductance/resistance of the memristive material comprised in the piezoelectric layer 104 may change a resonant frequency of the antenna 100.

The retention time can be defined as the amount of time during which the piezoelectric layer 104 will retain its set state, for example the amount of time during which the memristive material comprised in the piezoelectric layer 104 will retain its conductance at a changed state. The retention time may be increased by increasing at least one of the number of voltage pulses, pulse width and/or pulse magnitude.

The piezoelectric layer 104 may be arranged to be set to the defined condition prior to a receiving and/or transmitting operation of the antenna being performed. In such way, the antenna 100 may be pre-programmed or pre-set to the defined condition.

As discussed above, strain is generated by the magnetostrictive layer 102 by converting a magnetic field of a detected electromagnetic wave, i.e. the signal being detected by the antenna 100. The piezoelectric layer 104 may be configured to produce the voltage output based on a charge resulting from the received strain and the set condition of the piezoelectric layer 104. As such, the voltage output produced by the piezoelectric layer 104 may depend not only on the detected electromagnetic wave, but also on the set condition of the piezoelectric layer 104. For example, the voltage output may depend on the received strain, resulting from the detected electromagnetic wave, and the modified conductance of the memristive material comprised in the piezoelectric layer 104.

The piezoelectric layer 104 may be configured to produce the voltage output when a charge resulting from the received strain is equal to a threshold value defined based on the set condition of the piezoelectric layer. That is, the piezoelectric layer 104 may be configured to produce the voltage output only at the pre-programmed signal pattern acquisition. The piezoelectric layer 104 may be pre-programmed to respond to a specific signal pattern by employing the memory capabilities of the memristive material comprised therein. This can be realised by setting the piezoelectric layer 104 to the defined condition, corresponding to the signal pattern that a user wishes to detect.

In detail, the process of signal recognition by the memristive material comprised in the piezoelectric layer 104 may employ the switching nature of memristors. As discussed above, by application of a voltage, the conductance and the resistance of the memristive material may be changed.

FIG. 2 schematically depicts a thin-film bulk acoustic wave resonator (FBAR) 200, comprising a piezoelectric layer, in accordance with an example embodiment. The piezoelectric layer may be equated to the piezoelectric layer 104 shown in FIG. 1. The piezoelectric layer may be sandwiched between a first electrode 210 (for example, a top electrode) and a second electrode 216 (for example, a bottom electrode) to thereby form a thin-film bulk acoustic resonator (FBAR) 200.

The piezoelectric layer may comprise a plurality of layers. The plurality of layers of the piezoelectric layer may comprise a switchable resistance layer 212. The resistance of the switchable resistance layer 212 may be variable between a high resistance state and a low resistance state. The plurality of layers may also comprise a capacitive layer 214.

The charge generated by the piezoelectric layer, caused by the detected electromagnetic wave, may modulate a voltage across the capacitive layer 214 of the memristive material comprised in the piezoelectric layer. The overall resistance/impedance of the antenna 100 may be controlled by the switchable resistance layer 212. The resulting changes in at least one of a conductance, resistance, impedance and capacitance of the memristive material comprised in the piezoelectric layer may modulate the resonant frequency of the FBAR 200, thereby changing the resonant frequency of the antenna 100.

As discussed above, the antenna 100 operates by converting the electromagnetic signal into the mechanical strain produced in the magnetostrictive layer 102. The mechanical strain transferred into the piezoelectric layer 104 is then converted into a voltage. In detail, this may cause a potential difference to be induced in the capacitive layer 214. When the voltage across the capacitive layer 214 reaches a switching threshold, switching may occur in the memristive material. The switching threshold may be pre-programmed in the memristive material. The switching threshold may correlate with a known signal pattern expected to trigger the switching in the memristive material, enabling switching to occur only if a desired signal pattern is detected by the antenna 100.

Signals not corresponding to the desired signal pattern may be treated by the antenna 100 as noise and dropped at the time of reception. That is, such signals may not trigger switching of the memristive material.

The memristive material may comprise annealed aluminium nitride, AlN. However, the skilled person would appreciate that other piezoelectric materials exhibiting memristive properties may also be used.

The annealing may comprise O₂ annealing. The O₂ annealing may decrease the number of oxygen vacancies in an interface between the aluminium nitride layer and a top electrode of the FBAR. Through the annealing process, a high dielectric thin film may be formed. This high relative dielectric constant layer enables the memristive material to exhibit synaptic behaviour.

Importantly, the above-described configuration of the antenna 100 is particularly useful where there is a need to rapidly detect and identify a signal with a particular characteristic. As the piezoelectric layer 104 employs the memristive material comprised therein to trigger a response only when a desired signal pattern is detected, the need for interaction with a processing unit (such as a digital signal processor) is significantly reduced or eliminated. This allows for the computation to be done in the piezoelectric layer 104 without altering the mechanical stiffness of the layer, which would decrease its compliance and degrade the efficiency of the electromagnetic wave signal conversion. Thus, by enabling signal processing in the piezoelectric layer 104 without changing its mechanical state, an improvement can be achieved over the existing systems.

Furthermore, by enabling signal processing directly in the antenna 100, the signal path can be shortened, therefore accelerating the speed at which information can be extracted from the detected signal. As such, the antenna 100 may be suitable for applications where minimum delay is needed, such as detecting a radio frequency (RF) signal pattern reflected from a fast-moving object.

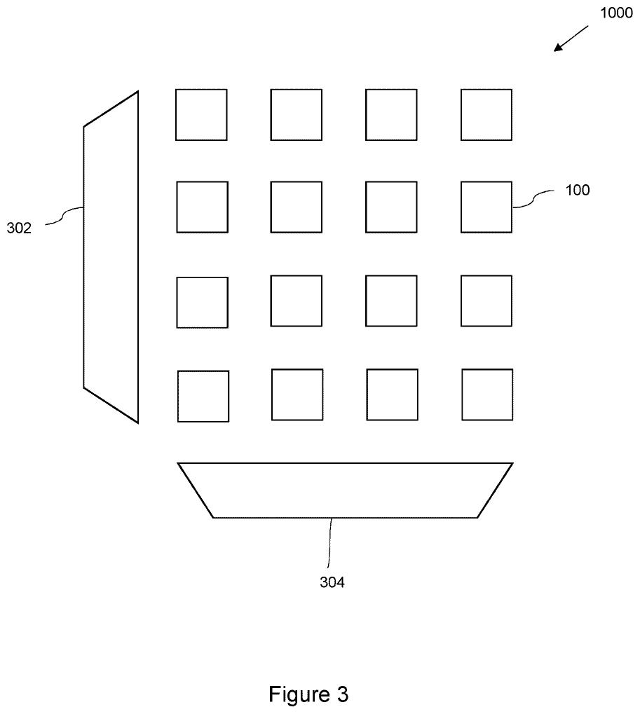

FIG. 3 schematically depicts an antenna array comprising a plurality of antennas, in accordance with an example embodiment. The antenna array 1000 comprises a plurality of antennas 100. The resonant frequencies of the plurality of antennas 100 may be the same. Alternatively or additionally, the resonant frequencies of the each of the plurality of antennas 100 may be different, such that a plurality of different resonant frequencies can be independently sensed. That is, each one of the plurality of antennas 100 may be arranged to individually be set to a defined condition by application of a voltage, in order to enable the multi-channel operation. The detected electromagnetic wave may be processed in parallel by each antenna 100 of the antenna array 1000. This may be achieved by using a network of a row multiplexer 302 and a column multiplexer 304 to individually address each antenna 100 of the antenna array 1000.

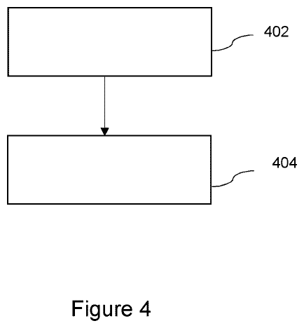

FIG. 4 schematically depicts a method of manufacturing an antenna, in accordance with an example embodiment. The antenna may be, for example, the antenna 100 described herein. The method comprises, in step 402, providing a piezoelectric layer comprising a memristive material. As discussed above in relation to FIG. 1, since the piezoelectric layer employs the memristive material comprised therein to trigger a response only when a desired signal pattern is detected, the need for interaction with a processing unit (such as a digital signal processor) is significantly reduced or eliminated. Furthermore, by enabling signal processing directly in the antenna, the signal path can be shortened, therefore accelerating the speed at which information can be extracted from the detected signal.

In step 404, the method comprises providing a magnetostrictive layer disposed on the piezoelectric layer. In another embodiment, the method may comprise providing a magnetostrictive layer first, with the piezoelectric layer comprising a memristive material disposed on the magnetostrictive layer. Alternating the layer order may enhance the performance of the antenna for certain applications, depending on the specific design. The method may also comprise providing a plurality of vertical stacks of piezoelectric-magnetostrictive layer pairs.

The method may also comprise the step of providing annealed aluminium nitride, AlN, as the memristive material. However, the skilled person would appreciate that other piezoelectric materials exhibiting memristive properties may also be used.

1. An antenna comprising:
a magnetostrictive layer configured to, in receive mode, convert a magnetic field of a detected electromagnetic wave into mechanical strain; and
a piezoelectric layer configured to, in receive mode, receive the mechanical strain from the magnetostrictive layer and produce a voltage output based thereon,
wherein the piezoelectric layer comprises a memristive material.

2. The antenna according to claim 1, wherein, in transmit mode, the piezoelectric layer is configured to receive a voltage input and produce mechanical strain based thereon, and the magnetostrictive layer is configured to receive the mechanical strain produced by the piezoelectric layer to produce and output an electromagnetic wave based thereon.

3. The antenna according to claim 1, wherein the piezoelectric layer is arranged to be set to a defined condition by application of a voltage and/or charge.

4. The antenna according to claim 3, wherein the piezoelectric layer is arranged to be set to the defined condition prior to a receiving and/or transmitting operation of the antenna being performed.

5. The antenna according to claim 3, wherein setting the piezoelectric layer to the defined condition comprises varying a conductance of the piezoelectric layer by application of the voltage.

6. The antenna according to claim 5, wherein the conductance of the piezoelectric layer is varied based on at least one of a frequency of the applied voltage and polarity of the applied voltage.

7. The antenna according to claim 3, wherein the piezoelectric layer is configured to retain the defined condition after the application of the voltage.

8. The antenna according to claim 3, wherein the piezoelectric layer is configured to produce the voltage output based on a charge resulting from the received mechanical strain and the defined condition of the piezoelectric layer.

9. The antenna according to claim 8, wherein the piezoelectric layer is configured to produce the voltage output when a charge resulting from the received mechanical strain is equal to a threshold value defined based on the set defined condition of the piezoelectric layer.

10. The antenna according to claim 1, wherein the memristive material comprises annealed aluminium nitride, AlN.

11. An antenna array comprising a plurality of antennas according to claim 1.

12. The antenna array according to claim 11, wherein each one of the plurality of antennas is arranged to individually be set to a defined condition by application of a voltage.

13. A method of manufacturing an antenna, comprising:
providing a piezoelectric layer comprising a memristive material; and
providing a magnetostrictive layer disposed on the piezoelectric layer.

14. The method according to claim 13, further comprising the step of providing annealed aluminium nitride, AlN, as the memristive material.
